(19) United States
(12) Patent Application Publication
(10) Pub. No.: US 2025/0329985 A1
(43) Pub. Date: Oct. 23, 2025

(54) Heterogeneous Photonic Circuits

(71) Applicant: Beacon Photonics Inc., Arlington, VA (US)

(72) Inventors: Christopher Vincent Poulton, Arlington, VA (US); Michael Grey Wood, Washington, DC (US); Gordon Arthur Keeler, Falls Church, VA (US)

(73) Assignee: Beacon Photonics Inc., Arlington, VA (US)

(21) Appl. No.: 19/187,462

(22) Filed: Apr. 23, 2025

Related U.S. Application Data
(60) Provisional application No. 63/637,650, filed on Apr. 23, 2024.

(51) Int. Cl. H01S 5/026; H01S 5/04; H01S 5/125; H01S 5/14; H01S 5/323

(52) U.S. Cl. CPC H01S 5/026; H01S 5/041; H01S 5/125; H01S 5/141; H01S 5/323

(57) ABSTRACT

Heterogeneous photonic circuits comprise a gain section optically coupled to a photonics section. The gain section can include at least one gain waveguide which can be formed from a III-V semiconductor material to provide optical gain. The gain waveguide can be coupled to optical components in the photonics section to form an integrated pump module. The photonics section can include a light-generating photonic circuit, which can comprise at least one waveguide doped with a rare-earth ion or transition-metal ion. Output from the integrated pump module and/or the light-generating photonic circuit can be tunable. Tuning can be implemented with feedback control.

### CROSS-REFERENCE TO RELATED APPLICATIONS

The present application claims a priority benefit, under 35 U.S.C. § 119(e), to U.S. provisional application Ser. No. 63/637,650, filed on Apr. 23, 2024, titled “Integrated Laser Module,” which provisional application is incorporated by reference herein in its entirety.

### FIELD OF THE DISCLOSURE

The present disclosure relates to heterogeneous photonic circuits comprising integrated pump modules that provide radiation to integrated light-generating photonic circuits.

### BACKGROUND

Laser modules can be used for optical excitation, also referred to as “pumping,” of other light-generating optical systems, such as doped solid-state and fiber-based amplifiers and lasers, or optically nonlinear devices that may include frequency doublers or optical parametric oscillators. Optical fiber is a commonly-used platform for making a laser module due to its flexibility and high performance. A typical conventional fiber-coupled laser module 100 is depicted in FIG. 1 and comprises an inexpensive Fabry-Pérot gain die 110 and a length of optical fiber 120 with a fiber Bragg grating (FBG) 125 that together form a stabilized laser module that can output light to pump a fiber-based light-generating optical system (such as an erbium-doped fiber amplifier).

### SUMMARY

Integrated photonics permits the fabrication of on-chip optical waveguides, passive and active optical components, and photonic circuits, of which some can be pumped with a laser source. However, the use of a fiber-based laser module to pump a photonic integrated circuit can greatly increase the size of the system compared to a photonic system that is entirely integrated onto a substrate using microfabrication processes. U se of a fiber-based laser module to pump a photonic integrated circuit can also increase complexity of the resulting system due to coupling between optical fibers and integrated optical waveguides that are disposed on a substrate or chip.

The inventors recognize and appreciate that an integrated pump module can be formed in a heterogeneous photonics circuit that comprises a gain section (which can be formed on a first substrate or chip) and a photonics section (which can be formed on a second substrate or chip different from the first substrate or chip). The photonics section can include one or more light-generating photonic circuits that can output at least one signal wavelength. The integrated pump module can be formed from optical components in the gain section and the photonics section of the heterogeneous photonic circuit. The integrated pump module can output useful radiation for photonic integrated circuits which may also be included in the photonics section. These integrated pump modules can have tunable optical characteristics (e.g., by tuning certain optical components within the photonics section). In some cases, the tuning can involve the use of feedback (e.g., to stabilize emission power and/or emission wavelength). The inventors also recognize that integrated pump modules described herein can be adapted for some photonic integrated circuits that use multiple integrated pump modules and have diverse architectures.

Some implementations relate to heterogeneous photonic circuits. Such photonic circuits can comprise a gain section. The gain section can comprise: a gain waveguide, integrated with the gain section, to amplify light by stimulated emission in a laser cavity and to guide the light amplified by stimulated emission in the gain section; and a photonics section optically coupled to the gain section. The photonics section can comprise: an optical waveguide, integrated with the photonics section and in optical communication with the gain waveguide, to receive the light amplified by stimulated emission from the gain section and to guide the light amplified by stimulated emission in the photonics section; an output coupler, integrated with the photonics section and in optical communication with the optical waveguide to partially form the laser cavity of an integrated pump module, the output coupler configured to transmit the light amplified by stimulated emission from the laser cavity as a pump beam having a pump wavelength; and a light-generating photonic circuit, integrated with the photonics section and in optical communication with the laser cavity. The light-generating photonic circuit can be configured to: receive the pump beam from the laser cavity, and output a signal beam at a signal wavelength different than the pump wavelength in response to optical pumping of the light-generating photonic circuit by the pump beam.

Some implementations relate to heterogeneous photonic circuits that comprise a gain section and a photonics section optically coupled to the gain section. The gain section can comprise: a plurality of gain waveguides, integrated with the gain section, wherein: each gain waveguide of the plurality of gain waveguides is configured to amplify light by stimulated emission in a laser cavity of a plurality of laser cavities formed partly in the gain section, and each gain waveguide of the plurality of gain waveguides is configured to guide the light amplified by stimulated emission in the gain section. The photonics section can comprise a plurality of optical waveguides, integrated with the photonics section and in optical communication with the plurality of gain waveguides, a plurality of output couplers, and a light-generating photonic circuit, integrated with the photonics section and in optical communication with the plurality of optical waveguides. Each optical waveguide of the plurality of optical waveguides can be arranged to receive the light amplified by stimulated emission from a corresponding gain waveguide of the plurality of gain waveguides and to guide the light amplified by stimulated emission in the photonics section. Each output coupler of the plurality of output couplers can be in optical communication with a corresponding optical waveguide of the plurality of optical waveguides to partially form a laser cavity of the plurality of laser cavities. Each laser cavity of the plurality of laser cavities can form an integrated pump module, and each output coupler of the plurality of output couplers is configured to transmit the light amplified by stimulated emission from the laser cavity and integrated pump module as a pump beam having a pump wavelength. The light-generating photonic circuit can be configured to receive a plurality of pump beams from the plurality of optical waveguides, wherein each pump beam of the plurality of pump beams comprises the light amplified by stimulated emission and has the pump wavelength. The light-generating photonic circuit can be further configured to output at least one signal beam at a signal wavelength different than the pump wavelength of each pump beam of the plurality of pump beams in response to optical pumping of the light-generating photonic circuit by the plurality of pump beams.

All combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. The terminology explicitly employed herein that also can appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein can be depicted exaggerated or enlarged in the drawings to facilitate an understanding of different features. In the drawings, like reference characters generally refer to like features (e.g., functionally similar and/or structurally similar components).

FIG. 1 depicts a conventional fiber-coupled laser module comprising a gain element and an optical fiber with a fiber Bragg grating (FBG).

FIG. 2A depicts a heterogeneous photonic circuit comprising a gain section optically coupled to a photonics section.

FIG. 2B depicts a heterogeneous photonic circuit comprising a gain section and a photonics section with a distributed Bragg reflector (DBR) formed in the photonics section with other optical components.

FIG. 2C depicts a heterogeneous photonic circuit comprising a gain section and a photonics section with a tunable DBR formed in the photonics section with other optical components.

FIG. 2D depicts a heterogeneous photonic circuit comprising a gain section and a photonics section with a wavelength filter and reflector formed in the photonics section with other optical components.

FIG. 3A depicts optical coupling of the gain section and the photonics section by butt-coupling waveguides in a gain die and a photonics die.

FIG. 3B depicts optical coupling of the gain section to the photonics section using a lens.

FIG. 3C depicts optical coupling of the gain section and the photonics section by embedding a gain die in a recess in a photonics die such that waveguides on the two dies align with each other.

FIG. 3D depicts optical coupling of the gain section and the photonics section by heterogeneous integration of the gain material along a waveguide in a photonics die.

FIG. 4A depicts tuning of a photonic waveguide with the thermo-optic effect.

FIG. 4B depicts tuning of a photonic waveguide with an electro-optic effect.

FIG. 4C depicts tuning of a photonic waveguide with the plasma dispersion effect.

FIG. 4D depicts tuning of a photonic waveguide with the photoelastic effect.

FIG. 4E depicts tuning of a photonic waveguide with a micro-electromechanical system (MEMS).

FIG. 5A depicts an integrated pump module configured to pump an on-chip optical amplifier.

FIG. 5B depicts an integrated pump module configured to pump an on-chip laser source.

FIG. 5C depicts an integrated pump module configured to pump a non-linear light-generating photonic circuit.

FIG. 6A depicts tuning of an integrated pump module with feedback derived from the output of a pumped optical amplifier, which output is detected by a photodetector.

FIG. 6B depicts tuning of the integrated pump module with feedback derived from the output of the pumped laser source, which output is detected by a photodetector.

FIG. 6C depicts tuning of the integrated pump module with feedback derived from the output of the pumped non-linear light-generating photonic circuit, which output is detected by a photodetector.

FIG. 7A depicts a photodetector formed with absorbing material integrated on a photonics die.

FIG. 7B depicts an external photodetector that is optically coupled to a photonics die by a grating coupler integrated with the photonics die.

FIG. 7C depicts an external photodetector that is coupled to the photonics die by an edge coupler.

FIG. 8A depicts tuning of an integrated pump module with feedback derived from a portion of the laser output detected by a photodetector.

FIG. 8B depicts tuning of an integrated pump module with feedback from a photodetector that senses residual pump light from a light-generating photonic circuit which is pumped by the integrated pump module.

FIG. 8C depicts tuning of the integrated pump module with feedback from a photodetector that detects light from an auxiliary photonic circuit which is pumped by the integrated pump module.

FIG. 8D depicts tuning of an integrated pump module with feedback from a photodetector that detects output from an auxiliary laser source in the system.

FIG. 8E depicts tuning of the integrated pump module with feedback from two photodetectors that detect residual pump light and a reference beam from an auxiliary photonic circuit pumped by the integrated pump module.

FIG. 9A depicts tuning of an integrated pump module with feedback from a portion of the laser output detected by a reverse-biased waveguide.

FIG. 9B depicts tuning of an integrated pump module with feedback from a reverse-biased waveguide that detects the residual pump from a light-generating photonic circuit pumped by the integrated pump module.

FIG. 9C depicts tuning of an integrated pump module with feedback from a reverse-biased waveguide that detects residual pump light from an auxiliary photonic circuit pumped by the integrated pump module.

FIG. 9D depicts tuning of an integrated pump module with feedback from the output of an auxiliary laser that is provided to and detected by a reverse-biased waveguide.

FIG. 9E depicts tuning of an integrated pump module with feedback from the output of an auxiliary photonic circuit that is detected by an array of two reverse-biased waveguides.

FIG. 9F depicts tuning of an integrated pump module with feedback from the output of an auxiliary laser that is detected by a reverse-biased waveguide along with a reference path for alignment validation.

FIG. 10A depicts an integrated pump module with a plurality of lasers formed in the gain section and the photonics section with DBRs.

FIG. 10B depicts an integrated pump module with a plurality of lasers formed in the gain section and the photonics section with tunable DB Rs.

FIG. 10C depicts an integrated pump module with a plurality of lasers formed in the gain section and the photonics section with DBRs in close proximity.

FIG. 10D depicts an integrated pump module with a plurality of lasers formed in the gain section and the photonics section where the DBRs are formed in close proximity to each other and to a tuning actuator.

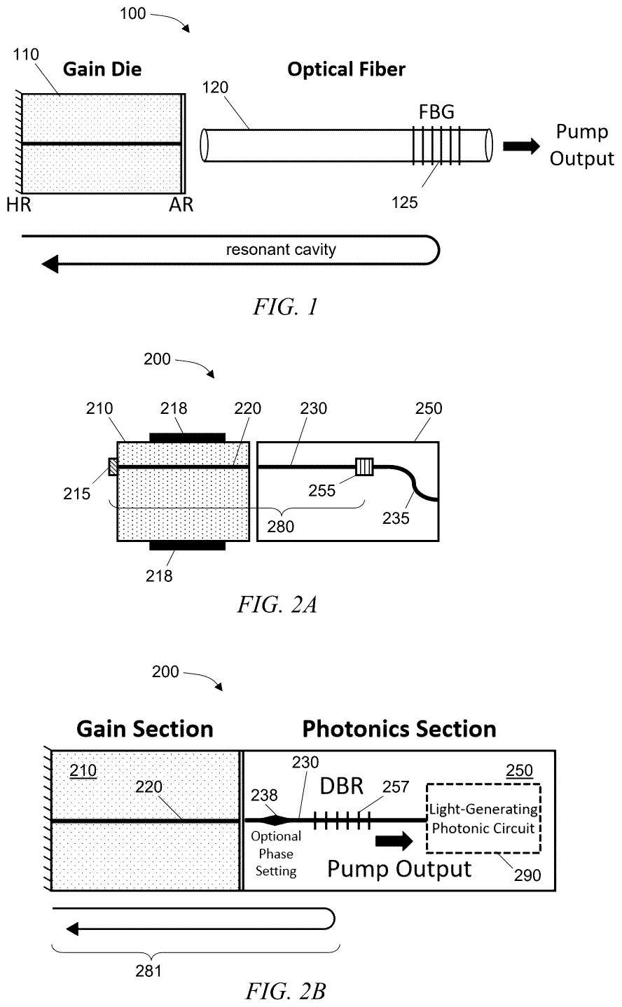

### DETAILED DESCRIPTION

### 1. Overview of a Heterogeneous Photonic Circuit

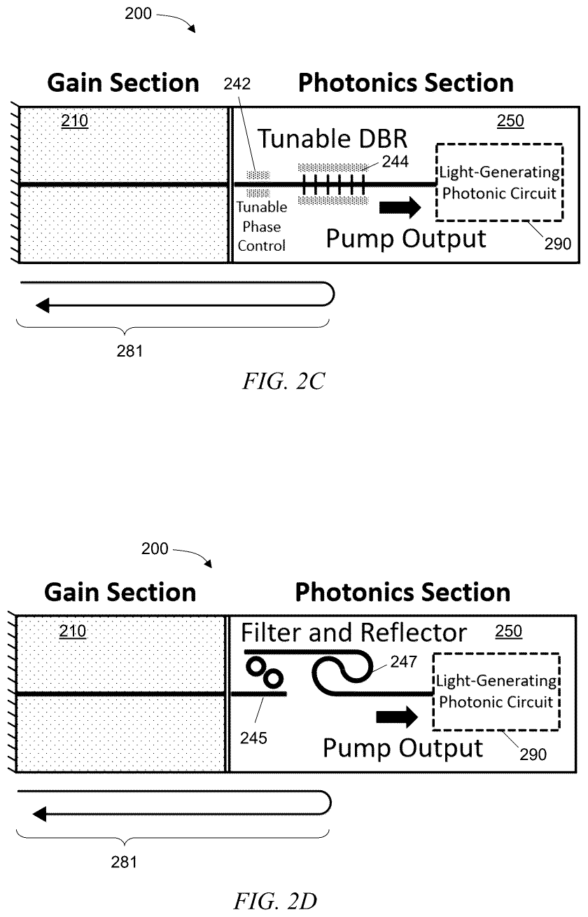

FIG. 2A is a simplified depiction of heterogeneous photonic circuit 200. The heterogeneous photonic circuit can be made by optically combining a gain section 210 with a photonics section 250 to at least produce, when activated, radiation at a desired wavelength that can pump a photonic circuit disposed in the photonics section 250, for example. The gain section 210 can comprise a gain die or gain chip having at least one integrated gain waveguide 220 in a material platform that provides optical gain around the desired wavelength. Possible materials that can be used for the gain section include III-V materials such as InP, GaN, GaAs, rare-earth or transition-metal doped waveguides, and/or other materials that can exhibit optical gain. The gain waveguide can guide light amplified by stimulated emission in the gain section 210. A high reflector 215 or other reflective structure can be disposed at an end of, or along, the gain waveguide 220 to reflect radiation in the gain waveguide toward the photonics section 250. To activate the gain section 210, the gain waveguide 220 may be optically pumped with another radiation source or may be driven electrically by passing a current through the gain waveguide. Electrical contacts 218 can be made to the gain section 210 for driving the electrical current through the gain waveguide.

The photonics section 250 can comprise an integrated photonics die or photonics chip having at least one optical waveguide 230 that optically couples to at least one gain waveguide 220 of the gain section 210. The optical waveguide 230 can receive and guide the light from the gain section 210 that is amplified by stimulated emission. The photonics section 250 can further comprise a reflector 255 (which may be a partial reflector or output coupler) disposed along the at least one optical waveguide 230 to reflect radiation from the photonics section back to the at least one gain waveguide 220 of the gain section (e.g., to form a resonant cavity or laser cavity) for amplification by stimulated emission. The reflector 255 can also transmit some of the light amplified in the gain waveguide(s) 220. Materials used to make the photonics section 250 can include, but are not limited to, silicon, silicon nitride, silicon dioxide, alumina, tantala, lithium niobate, lithium tantalate, and other materials used in microfabrication processes. Waveguides in the photonics section generally do not provide optical gain for the integrated pump module.

The gain section 210 and the photonics section 250 can be fabricated separately, e.g., using different microfabrication processes or even using different foundries, and subsequently coupled together optically. In some implementations, the gain section and the photonics section can be integrated together on the same substrate and/or in the same package. The heterogeneous photonic circuit 200 is formed by at least optically coupling the gain section 210 with the photonics section 250.

When optically coupled together, the gain section 210 and the photonics section 250 can form at least an integrated pump module 280. The integrated pump module 280 comprises an optically-active cavity such as an integrated laser cavity and/or an integrated optical amplifier. The integrated pump module 280 can be defined by a gain waveguide 220 of the gain section 210 that is optically coupled to an optical waveguide 230 in the photonics section 250. The integrated pump module 280 can further be defined by a high reflector 215 in optical communication with the gain waveguide 220 and/or a reflector 255 disposed along the coupled optical waveguide 230 in the photonics section 250. In the case of an optical amplifier, one or no reflectors may be used, and/or the reflectors may have low reflectance values (e.g., less than 50%).

The gain section 210 may or may not include a high reflector 215 formed by an additive process that defines the integrated pump module 280 of the heterogeneous photonic circuit 200. In some cases, the high reflector 215 can be formed additively by deposition of a metal and/or a multilayer dielectric coating. In other cases, the high reflector 215 can be formed as a cleaved or etched facet at the end of the gain waveguide 220 or other waveguide coupled to the gain waveguide. In yet other cases, the high reflector 215 can be formed as a distributed Bragg reflector (DBR) or other resonant reflective filter patterned in the gain section 210 in optical communication with the gain waveguide 220. In some cases, the integrated pump module 280 in the gain section 210 can be implemented with a waveguide formed in a loop (e.g., a Sagnac loop or ring-shaped cavity) that comprises, at least in part, the gain waveguide 220.

There may or may not be a reflector 255 disposed in the photonics section for some implementations. In some implementations, the second reflector 255 of the integrated pump module 280 can be disposed in the gain section 210 and output from the gain section optically coupled to the optical waveguide 230 of the photonics section 250.

In some implementations, the photonics section 250 may further comprise only an output waveguide 235 to provide radiation at the desired wavelength as optical output for off-chip devices or applications. In some cases, the photonics section 250 can further comprise additional integrated optical components (e.g., one or more partial reflectors, one or more waveguides coupled to the output waveguide 235, one or more optical filters, one or more phase modulators, etc.) In some implementations, the photonics section 250 can include one or more photonic integrated circuits coupled to the integrated pump module 280. Materials used to form the additional integrated optical components and/or the photonic integrated circuit(s) can include some of the same materials used to form the integrated pump module 280 and may further include different materials. In some implementations, additional integrated optical components and/or a photonic integrated circuit of the photonics section 250 may be configured to provide optical feedback into the gain section 210, thereby controlling characteristics of radiation output from the optically-active cavity, such as wavelength and amplitude.

### 2. Implementations of Heterogeneous Photonic Circuits

Various implementations of heterogeneous photonic circuits are described in this section. FIG. 2B depicts an example of a heterogeneous photonic circuit 200 in which an optical filter and reflector in the photonics section are implemented with a waveguide-based distributed Bragg reflector (DBR) 257 that also acts as an output coupler for the integrated pump module's laser cavity 281. The waveguide-based DBR can be formed by microfabricating periodic perturbations on or near the optical waveguide 230 in the photonics section 250 that couples to the gain waveguide 220 in the gain section 210. The periodic perturbations cause optical reflection at the Bragg wavelength. Optionally, there can also be a passive (fixed) phase-setting component 238, such as an extra length of waveguide, delay, or bump, to set the phase of reflection. Phase-setting components can be useful if multiple integrated pump modules are used and it is desired for them to have identical cavity lengths but different phases.

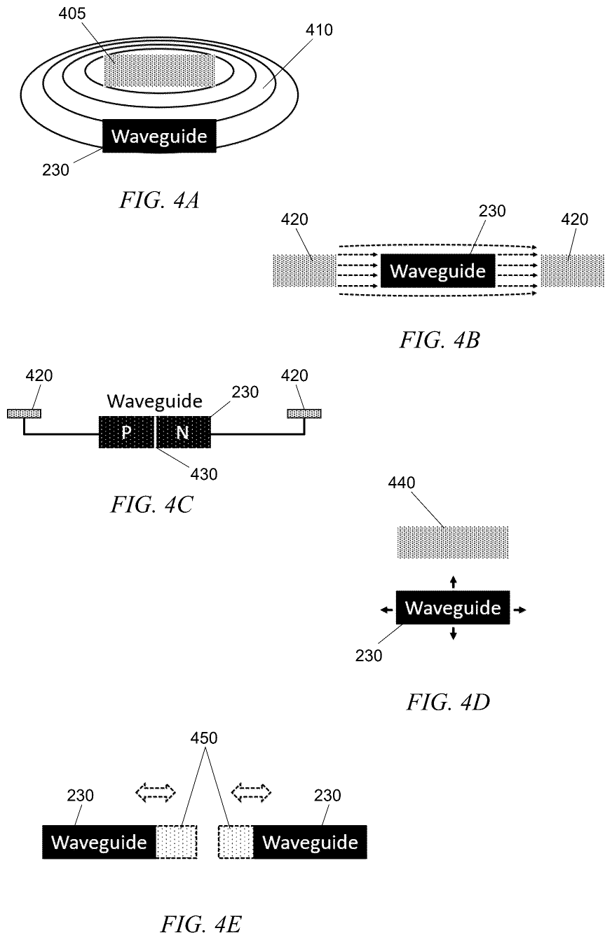

The heterogeneous photonic circuit 200 of FIG. 2C comprises a tunable phase control element 242 and a tunable DBR 244. Optical tuning of the lasing wavelength and/or phase in the laser cavity 281 and output from the laser cavity can be achieved by changing the refractive index of the waveguide 230 with these tunable components. The tunable phase control element 242 can control the optical path length of the laser cavity, and the tunable D B R 244 can control the passband of the D B R. A n active tuning mechanism that can be used for either or both of the tunable phase control element 242 and the tunable DBR 244 comprises a heater, piezoelectric element, electro-optic element, etc. disposed in close proximity to or along the waveguide 230. Some examples of active tuning mechanisms are depicted in FIG. 4A through FIG. 4E.

Reflectors other than a D B R can be used in the photonics section 250 at one end of the laser cavity 281. Some reflectors, like the DB R, can include wavelength filtering and can be tunable in wavelength and/or phase. Some of these devices can comprise one or more ring resonators, one or more photonic crystals, one or more dichroic filters, one or more M ach-Zehnder interferometers, or some combination of these components.

FIG. 2D depicts a heterogeneous photonic circuit 200 comprising a filter 245 and a reflector 247 to terminate the laser cavity 281. In some implementations, the filter 245 and reflector 247 can be formed from waveguide elements (ring resonators, waveguide loop) in the photonics sections 250, though in some cases one or both of these components can be formed in the gain section 210. Possible reflectors that could be implemented in the photonics section 250, and/or in the gain section 210, include Sagnac loops, gratings, step refractive index changes, coated facets, or Fabry-Pérot cavities. Some of the optical structures, such as the DBR, can combine wavelength filtering and reflecting functionalities within a single structure.

Optical output from the laser cavity 281 for the integrated pump modules described in FIG. 2B through FIG. 2D can be provided to a photonic circuit integrated in the photonics section 250. In some implementations, the photonic circuit can be a light-generating photonic circuit 290 that includes gain media and/or nonlinear optical material.

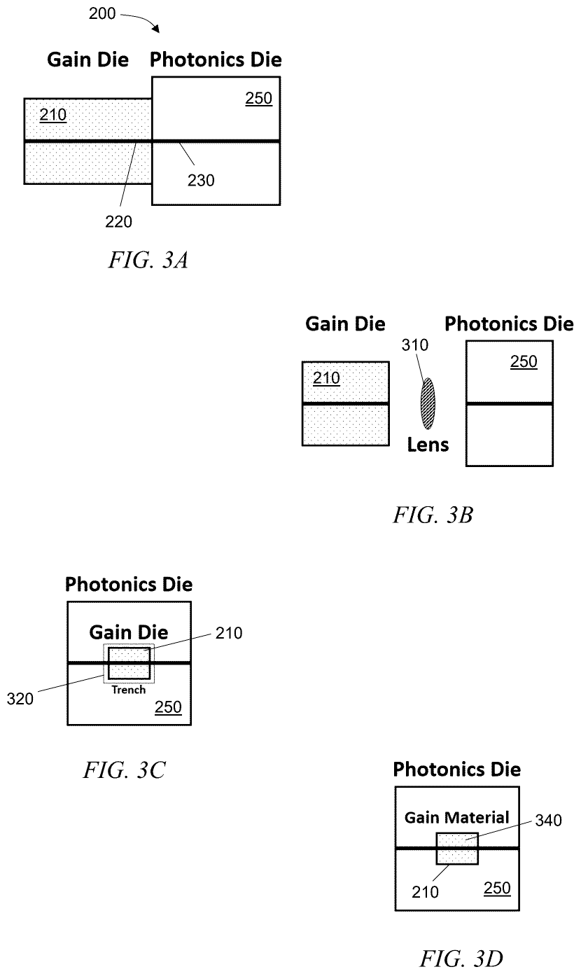

FIG. 3A through FIG. 3D depict examples of different ways to combine and optically couple the gain section 210 and the photonics section 250 to form the heterogeneous photonic circuit 200. One possibility, depicted in FIG. 3A, is to butt-couple the facet of the gain waveguide 220 in the gain section 210 to the facet of the optical waveguide 230 in the photonics section 210. In this example, the gain section 210 comprises a first (gain) die and the photonics section 250 comprises a second (photonics) die. Each die can be a singulated from a wafer on which the devices were microfabricated. The dies can be rectangular in shape or square, though other shapes are possible. The gain die and the photonics die can be fabricated on different wafers that went through separate microfabrication processes before the dies were singulated. When combined to form the heterogeneous photonic circuit 200, the mating waveguides and their facets are aligned. The gain die and photonics die can be mechanically coupled to each other after alignment (e.g., bonded together or mounted on a common substrate).

FIG. 3B depicts another coupling approach in which the two die are optically coupled to each other through an intermediate optical system such as a lensing system 310 comprising one or more lenses. In some cases, the lensing system can comprise one or more microlenses and/or one or more graded-refractive-index (GRIN) lenses.

The gain section 210 and the photonics section 250 can also be combined through hybrid or heterogeneous integration processes. FIG. 3C depicts such an approach in which the gain section 210 (implemented as a first die) is embedded in a trench 320 within the photonics section 250 (implemented as a second die) such that one or more waveguides in the gain section align with one or more waveguides in the photonics section. In such a hybrid integration, the gain section 210 can be nested within the photonics section 250 such that the two sections are closely integrated and can look like a single physical unit or single die. FIG. 3D depicts heterogeneous integration of the gain section 210 (implemented as gain material) in the photonics section 250 (implemented as a photonics die). In this case, the gain material 340 may be deposited on the photonics die (e.g., by a physical deposition process) and located along a waveguide. The gain section does not comprise a separate die.

In some implementations, the gain section 210 and the photonics section 250 can contain more than one optically-coupled interface, as depicted for the examples of FIG. 3C and FIG. 3D. For example, a gain waveguide may couple at both ends to two waveguides of the photonics section. In some cases, one or more waveguides in the gain section 210 can be coupled or mated to corresponding one or more waveguides in the photonics section 250. Although a waveguide(s) in the gain section 210 can be formed from different materials and have different dimensions than its mate(s) to which it couples in the photonics section 250, preferably the coupled waveguides are designed to support approximately identical spatial optical modes at their coupling location to improve coupling efficiency between the mating pair(s) of waveguides. If the coupled waveguides do not support matching waveguide modes, mode converters integrated with the waveguides can be used to generate approximately identical modes at the coupling location and improve the coupling efficiency between the waveguides.

There are several different techniques that can be used for phase and/or wavelength tuning of the output from the laser cavity 281 of the heterogeneous photonic circuit 200. FIG. 4A depicts an example of one of these techniques that utilizes the thermo-optic effect. In this approach, a heating element 405 can be integrated into the gain section 210 or photonics section 250 such that it is in close proximity to and thermally couples heat 410 to an optical component (e.g., length of waveguide 230, DBR, ring resonator, etc.) that induces the optical tuning. The heating element 405 can comprise a region of resistive metal or semiconductor material through which electrical current is passed, in some cases. In some implementations, the heating element 405 comprises electrical contacts arranged to drive electrical current through an optical component (e.g., along or across a waveguide 230), such that the current induces heating of the optical component.

FIG. 4B depicts an implementation that utilizes the electro-optic effect (e.g., the Pockels or Kerr effect) for phase or wavelength tuning. The electro-optic effect can be induced by applying an electric field along or across a waveguide 230 using metal electrodes 420. The applied electric field can induce a change in the refractive index of the material through which the applied electric field passes and thus change the phase of an optical wave travelling through the material.

In another approach depicted in FIG. 4C, the plasma dispersion effect can be employed by injecting or removing carriers in a PN junction 430, PIN junction, or a metal-oxide-semiconductor (MOS) capacitor-like structure formed in and/or adjacent to a waveguide 230. The injected or removed carriers can change the refractive index of the waveguide. Charge can be injected or removed from the device by applying a voltage to electrodes 420 coupled to the device (e.g., coupled to p-type material and n-type material in a PN junction 430 or PIN junction).

In some implementations, the photoelastic, acousto-optic, or stress-optic effect can be used for optical tuning by inducing stress across the waveguide 230 or other optical component with a piezoelectric element 440, as depicted in FIG. 4D. The piezoelectric element 440 can be mechanically coupled to the waveguide 230 or other optical component (e.g., DBR, ring resonator, filter, etc.) such that expansion and/or contraction of the piezoelectric element 440 induces mechanical stress in the waveguide 230 or other optical component. The induced stress can cause a change in phase of an optical wave travelling through the stressed material.

In some implementations, a micro-electromechanical system (MEMS) can be used to dynamically tune an optical component by physically moving one or more elements of the optical component (e.g., moving a suspended MEMS mirror or moving evanescently coupled waveguides 230). In FIG. 4E, two evanescently coupled waveguides 230 are moved by MEMs actuators 450 that are mechanically coupled to the two waveguides 230. The movement of the waveguides 230 can significantly change the amount of evanescent coupling between the two waveguides. Other optical components that may be tuned using MEMs include, but are not limited to, reflectors, filters, and/or phase control elements.

Each of the tuning mechanisms described in connection with FIG. 4A through FIG. 4E can be utilized to tune the performance of a reflector, filter, and/or phase control element within the photonics section 250 of a heterogeneous photonic circuit 200. The tuning mechanisms can involve changing the refractive index of the waveguides (e.g., changing the refractive index of the waveguide's core and/or cladding materials) to change optical characteristics of the device, such as changing the optical bandwidth, reflectance, and/or changing the coupling between waveguides of the device. These changes in device characteristics can alter the integrated pump module performance such as the amount of pump power output from the device, the wavelength, and/or the linewidth output from the device.

### 3. Light-Generating Photonic Circuits

In some cases, the photonics section 250 of a heterogeneous photonic circuit 200 can include a light-generating photonic circuit that is optically pumped by an optical source (e.g., the integrated pump module 280 of a heterogeneous photonic circuit). The light-generating photonic circuit can generate light at a signal wavelength that is distinct from the pump wavelength output from the integrated pump module 280 and used to optically pump the light-generating photonic circuit. In some implementations, the light-generating photonic circuit comprises gain material that exhibits optical gain at the signal wavelength.

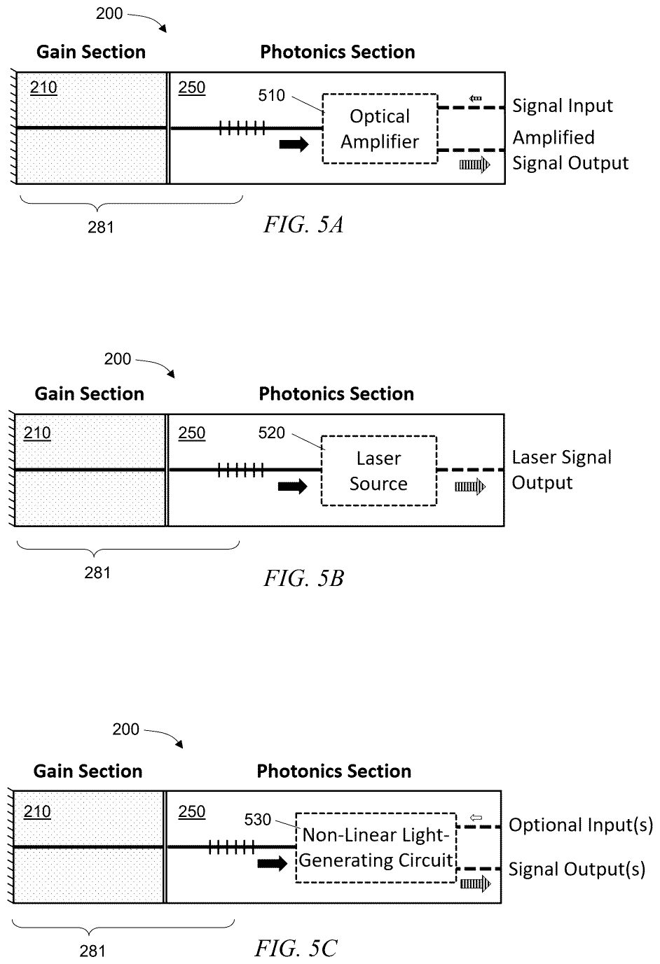

FIG. 5A depicts an implementation of a heterogeneous photonic circuit 200 in which an optical amplifier 510 is integrated in the photonics section 250 and is pumped by output from a laser cavity 281 of an integrated pump module formed partially in the gain section 210 and partially in the photonics section 250. The optical amplifier 510 also receives an external signal to be amplified. The heterogeneous photonic circuit 200 can output the amplified signal.

FIG. 5B depicts another implementation of a heterogeneous photonic circuit 200 comprising a light-generating photonic circuit. In this implementation, the optically-pumped light-generating photonic circuit comprises a laser source 520 that outputs laser radiation, which could be at a selected signal wavelength. The laser source 520 is optically pumped by an integrated pump module having a laser cavity 281 in the heterogeneous photonic circuit 200.

Optical gain can be provided at a signal wavelength in the photonics section 250 by, for example, doping waveguides in the photonics section certain ions, such as transition-metal ions (Ti, Cr, Fe, etc.) or rare-earth ions (erbium, thulium, neodymium, holmium, ytterbium, praseodymium, etc.). Dopants can be introduced into a waveguide core and/or cladding through several ways such as co-sputtering with various oxides (Al₂O₃, TeO₂, SiO₂, ErO₃, etc.), atomic layer deposition, ion implantation, or ion exchange.

Other implementations to obtain optical gain can use stimulated Brillouin scattering or stimulated Raman scattering in the photonics section 250. Both of these techniques can provide gain at a signal wavelength when optically pumped, e.g., from an integrated pump module implemented at least in part on the gain section 210.

Optical amplifiers 510 and laser sources 520 can have a longer output wavelength than the pump wavelength from the integrated pump module used to excite them (i.e., the pump wavelength has a larger photon energy). For waveguides doped with ions to provide optical gain within the light-generating photonic circuit, the pump photons excite the ions to a higher energy state which later generate output light at a longer wavelength when the excited ions decay through spontaneous or stimulated emission. For amplifiers and lasers that utilize stimulated Brillouin scattering or stimulated Raman scattering, pump photons generate a phonon and a lower-energy signal photon.

Other examples of optically-pumped, light-generating photonic circuits can employ non-linear optics, such as a frequency doubler, a comb generator, an optical parametric downconverter, an optical parametric amplifier, or an optical parametric oscillator. FIG. 5C depicts an implementation of a heterogeneous photonic circuit 200 that includes a non-linear light-generating photonic circuit 530. The non-linear light-generating photonic circuit 530 is pumped by, or receives radiation from, an integrated pump module (comprising the laser cavity 281 in this example) that is part of the heterogeneous photonic circuit 200. The non-linear light-generating photonic circuit 530 can have no additional optical inputs or may have one or more additional optional optical inputs. There can be one or more optical outputs from the non-linear light-generating photonic circuit 530.

Non-linear light-generating photonic circuits 530 can have a complex relationship between pump and signal wavelengths, such as occurs for optical parametric conversion. Generally, the non-linear circuit will convert a set of input photons into another set of converted photons while conserving the total photon energy between the two sets of photons. The pump radiation, and potentially other optical inputs, are contained in the input set of photons and the signal is contained in the converted set of photons. Depending on the number of photons converted, the signal wavelength could be larger or smaller than the pump wavelength. Furthermore, it is possible to have more than one wavelength in the converted set. The additional wavelength in the converted set of photons is commonly called an idler wavelength and, in some cases, can also be considered a signal output.

### 4. Feedback Control

As previously mentioned, the ability to dynamically tune the reflector, filter, and/or phase control in the photonics section 250 can enable tuning of the integrated pump module's optical characteristics. Dynamically altering laser metrics such as pump wavelength and optical power is useful for improving performance of the nonlinear light-generating photonic circuit 530, for example, or other light-generating photonic circuit implemented in the photonics section 250. Feedback can be used in some cases to control tunable parameters of the integrated pump module. There are several ways to implement feedback. One class of feedback circuits directly monitors the output(s) from the light-generating photonic circuit in the photonics section 250.

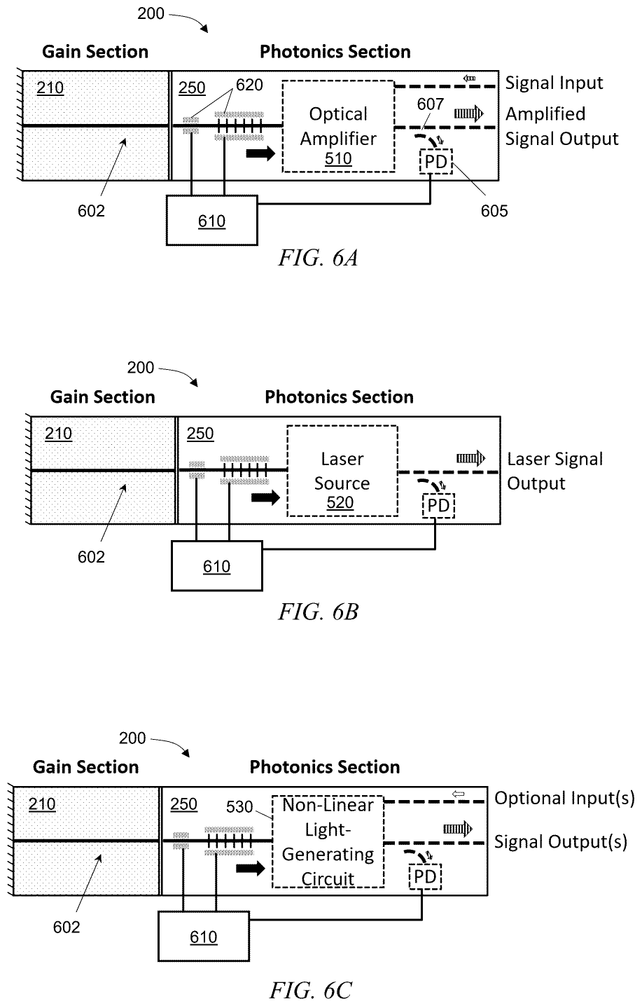

FIG. 6A depicts an example feedback system for a heterogeneous photonic circuit 200 comprising an optical amplifier 510. The amplified signal output can be monitored with a photodetector 605 integrated within the photonics section 250. In the illustrated example, a portion of the amplified signal output is tapped off by a coupler 607 (which could be implemented as an evanescent waveguide coupler, a directional coupler, or multi-mode interference splitter). The light tapped off is incident on the photodetector 605. The signal from the photodetector can be provided to a processor 610 for processing. The processor 610 can output one or more control signals to adjust one or more tunable optical components 620 (e.g., phase tuner, filter, reflector) that affect operation of the integrated pump module 602 (such as an integrated laser), which in turn can affect the output of the light-generating photonic circuit (the optical amplifier 510 in the illustrated example). The tunable portion of the heterogeneous photonic circuit 200 can then be tuned using feedback in an automated or semi-automated way to improve output power, for example.

Monitoring optical output(s) from the light-generating photonic circuit for feedback can be utilized in other heterogeneous photonic circuits 200. FIG. 6B depicts a feedback implementation for a heterogeneous photonic circuit 200 in which light output from a laser source 520 is monitored for feedback purposes. The laser source 520 can be optically pumped with an integrated pump module 602 (e.g., another laser) that is integrated in the heterogeneous photonic circuit 200. FIG. 6C depicts a feedback implementation for a heterogeneous photonic circuit 200 in which light output (the signal output in this example) from a nonlinear light-generating photonic circuit 530 is monitored for feedback purposes.

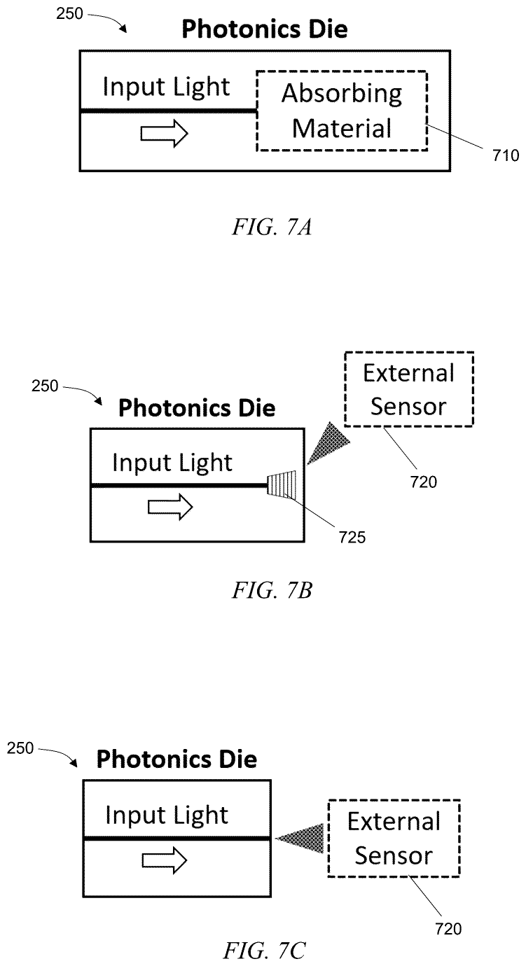

Photodetection can be implemented in more than one way within, or in combination with, the photonics section 250. FIG. 7A depicts an implementation in an optically absorbing material 710 is disposed within the photonics section 250 (implemented as a photonics die in this example). The absorbing material 710 could be semiconductor material (e.g., a p-n or p-i-n junction disposed in the photonics section). The carriers generated from absorption can be electrically read to provide an indication of the input light power to the absorbing material 710.

FIG. 7B depicts another implementation of photodetection which uses an external sensor 720 that is mounted external to and optically coupled to the photonics section 250. The external sensor 720 could be a photodetector. A n external sensor 720 can be beneficial when an absorbing material or metal interconnects are not available on the photonics section 250 or are difficult to integrate with the photonics section. In some cases, light from the photonics section 250 can be coupled through free space (e.g., by the use of a grating coupler 725 or other coupling element).

Another way to couple to an external sensor 720 is to use edge coupling, as depicted in FIG. 7C. Even though the external sensor 720 may not be formed on a photonics die, it may be considered part of the photonics section 250 in some cases and not part of the gain section 210. For example, the external sensor 720 does not provide optical gain and is coupled to optical components in the photonics section 250. The detection schemes depicted in FIG. 7A through FIG. 7C can be used for photodetection in other photonics sections described herein.

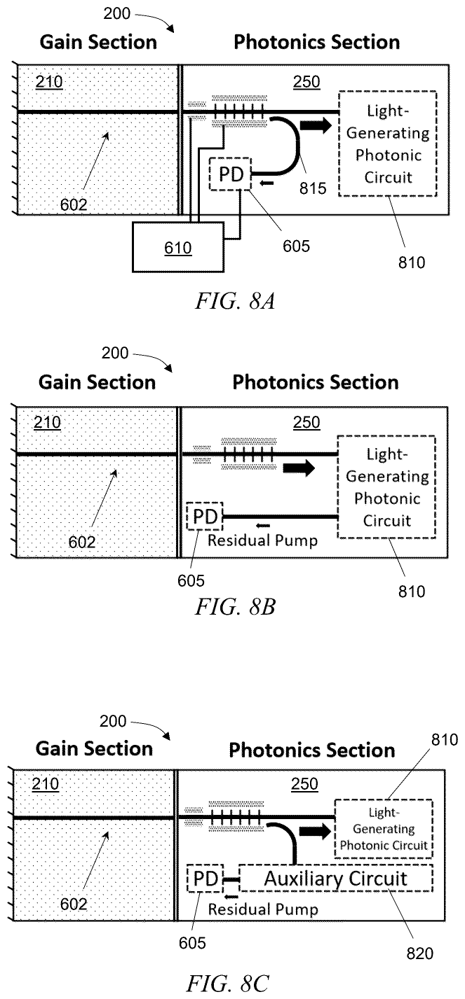

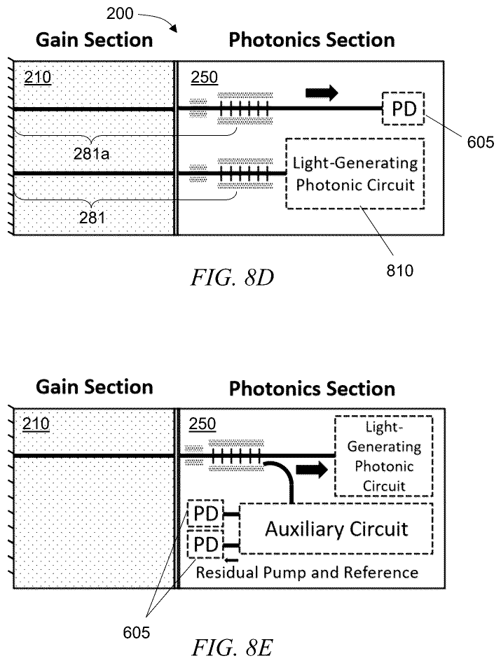

In some implementations, output from the integrated pump module 602 can be monitored for feedback instead of, or in addition to, output(s) from optical component(s) in the photonics section. FIG. 8A depicts one example implementation in which output from the integrated pump module 602 is provided to the light-generating photonic circuit 810, is sampled with an evanescently coupled waveguide 815, and the sampled output is detected with a photodetector 605. Such measurement can enable feedback control (as described in connection with FIG. 6A) for improving pump output power, adjusting the wavelength, and/or adjusting the phase from an integrated pump module 602 that is implemented, at least in part, in the gain section 210 (e.g., a pump module comprising a laser cavity formed partly in the gain section and partly in the photonics section).

FIG. 8B depicts another feedback approach in which a residual pump signal is monitored with a photodetector 605. The feedback loop and processor 610 are not shown in FIG. 8B to simplify the illustration. The photodetector 605 is arranged to receive a residual pump signal from the light-generating photonic circuit 810 after the pump beam has interacted with the light-generating photonic circuit. Monitoring the residual pump signal can give an indication of how effectively the pump interacts with the light-generating photonic circuit 810. For example, a high residual pump power can mean that the pump beam was not effectively absorbed and/or converted to power at another wavelength (e.g., the signal wavelength). Tuning the wavelength of the integrated pump module 602 may increase absorption and/or conversion of the pump power by the light-generating photonic circuit 810, increase signal output, and dynamically reduce the residual pump power detected by the photodetector 605.

In some implementations, an auxiliary photonics circuit 820 (FIG. 8C) comprising a spectrometer or wavelength-dependent absorbers and/or detectors can be implemented, at least in part, in the photonics section 250. The auxiliary photonic circuit 820 can infer information about the pump wavelength in some cases (e.g., whether the pump wavelength is tuned to the peak absorption wavelength for gain material in the light-generating photonic circuit 810). FIG. 8C depicts an example implementation in which a portion of the pump output is incident to the auxiliary photonics circuit 820 and residual pump from the auxiliary photonics circuit 820 is detected with a photodetector 605. This monitoring scheme can be useful when a residual pump from the light-generating photonic circuit 810 is not expected. The auxiliary photonic circuit 820 can be similar to or comprise a copy of the light-generating photonic circuit 810, or a much simpler circuit such as a single rare-earth-doped or non-linear waveguide.

There can be cases where the measurement of optical output from an auxiliary optical device formed on the heterogeneous photonic circuit 200 can be used to tune a main optical device formed on the heterogeneous photonic circuit 200. FIG. 8D depicts an example implementation where an auxiliary laser cavity 281a is formed as the auxiliary optical device. Output from the auxiliary laser cavity 281a is detected by a photodetector 605. The signal from the photodetector 605 can be used in a feedback loop (not shown) to tune optical components in both the main laser cavity 281 and/or the auxiliary laser cavity 281a to improve optical output from both cavities. Since the optical devices are formed in close proximity, they can behave essentially identically. In some cases, sweeps, search processes, dithering, or other procedures can be carried out with the auxiliary optical component to find a desirable operating configuration while the main optical component connected to the light-generating photonic circuit 810 operates unaffected by the exploratory changes being carried out with the auxiliary optical component (auxiliary laser cavity 281a in this example). Once a new operating configuration is identified with the auxiliary optical component, the main optical component can be switched to operating in the new operating configuration.

In some configurations, it can be desirable to use two or more photodetectors 605 for feedback purposes to tune the pump wavelength, as depicted in FIG. 8E. An example implementation could use differential photodetectors: one photodetector to detect output of the pump radiation from a passive reference waveguide and one photodetector to detect optical output of the pump radiation from a rare-earth-doped or non-linear waveguide.

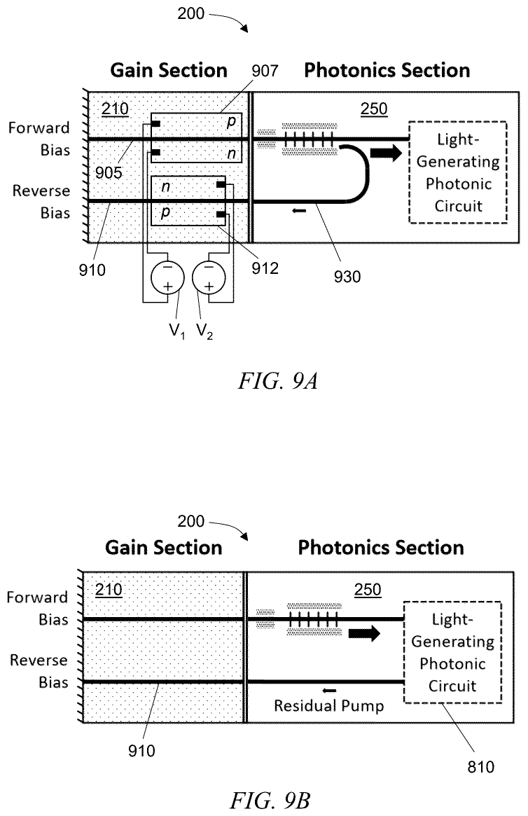

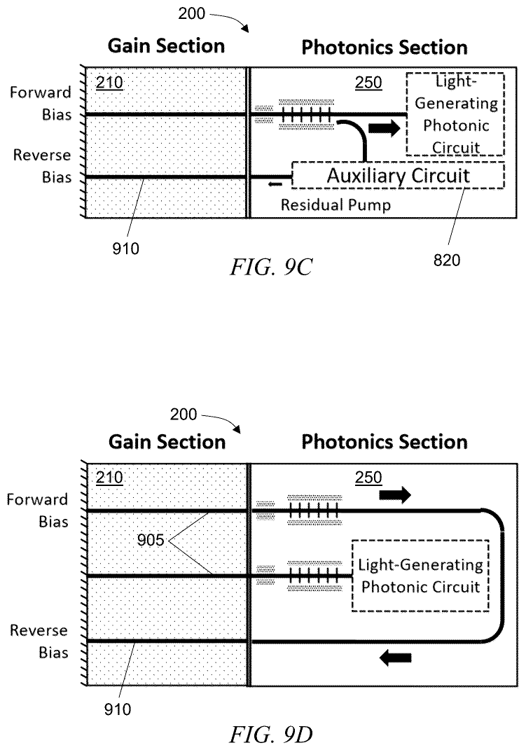

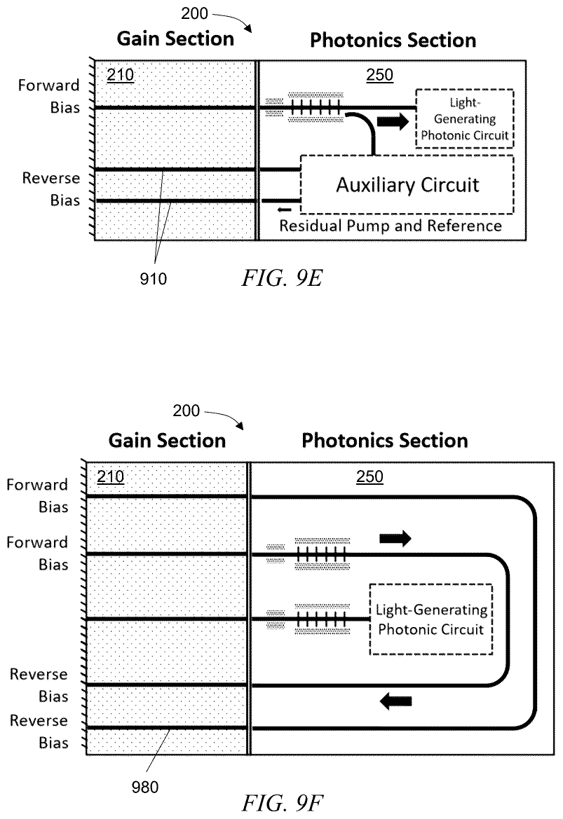

In some cases, photodetection of the pump wavelength can be implemented in the gain section 210 additionally or alternatively to photodetection in the photonics section 250. FIG. 9A, FIG. 9B, FIG. 9C, FIG. 9D, and FIG. 9E depict example implementations comprising photodetection of the pump wavelength in the gain section 210. FIG. 9A shows one example of how forward biasing and reverse biasing can be implemented in the gain section 210. A forward-biased waveguide 905 can comprise a first p-n junction 907 that is forward biased with a first voltage source V₁ during operation to provide optical gain. A detection waveguide 910 in the gain section 210 can comprise an optical waveguide with a second p-n junction 912 that may or may not be reverse biased with a second voltage source V₂ during operation to produce a photodetector-like response when coupled to light at the pump wavelength (e.g., wavelengths exhibiting optical gain when the waveguide is forward biased). Such photodetection schemes can be used for any of the feedback implementations described herein.

In FIG. 9A, the detection waveguide 910 is configured to monitor optical output from the integrated pump module (in optical communication with a coupler that samples the output from the integrated pump module). In such implementations, an optical waveguide 930 in the photonics section 250 optically couples to the detection waveguide 910. The optical coupling between the waveguides of the gain section 210 and mating waveguides of the photonics section 250 can be done in any manner described herein.

In FIG. 9B, the detection waveguide 910 is configured to monitor residual pump radiation from the light-generating photonic circuit 810. In FIG. 9C, the detection waveguide 910 is used to monitor output from the auxiliary photonic circuit 820.

To support both light emission under forward bias and light detection under reverse bias, the gain section 210 can comprise metal contacts and/or a doping profile patterned to electrically isolate the forward-biased waveguides 905 and the detection waveguides 910. The light-emitting region (forward-biased waveguides 905) can be forward-biased in a current-controlled manner and receive input current from a suitable forward-bias control circuit, which may or may not be microfabricated and implemented, at least in part, in the gain section 210 or the photonics section 250. The light-detection regions (detection waveguides 910) can be reverse-biased with a voltage bias generated with a current going to a transimpedance amplifier, all or some of which may or may not be implemented in the gain section 210.

In FIG. 9D, the gain section 210 includes three waveguides coupled to mating waveguides in the photonics section 250. Two waveguides in the gain section 210 are configured to be operated as forward-biased waveguides 905 that can output a pump laser beam and an auxiliary laser beam, respectively. The third waveguide is configured for operation as a detection waveguide 910 and can be used to measure optical output from the auxiliary laser cavity (e.g., to infer information about the pump laser beam, such as its wavelength, amplitude, and/or phase). Information obtained about the auxiliary laser output can be used to adjust the phase, wavelength, and/or amplitude of the main pump laser, which may couple to a light-generating photonic circuit.

The gain section for the heterogeneous photonic circuit 200 of FIG. 9E also includes three waveguides in the gain section 210 that are coupled to mating waveguides in the photonics section 250. Two of these waveguides in the gain section 210 are configured for operation as detection waveguides 910 and can be used for making a differential measurement of outputs from an auxiliary circuit in the photonics sections 250, as described above in connection with FIG. 8E.

FIG. 9F depicts an implementation of a heterogeneous photonic circuit 200 in which five waveguides in the gain section couple to five mating waveguides in the photonics section 250. A n untuned feedback waveguide 980 is added to the tuning circuit of FIG. 9D to provide an alignment reference independent from the tuning circuit. The added waveguides and measurement can be beneficial in certain integrated embodiments, for example, to align and butt-couple waveguides in the gain section 210 to mating waveguides in the photonics sections for the implementations of FIG. 9A through FIG. 9F during integration of the gain section 210 and photonics section 250.

### 5. Multi-Pumped Light-Generating Photonic Circuits

Some implementations of light-generating photonic circuits can use multiple pump beam inputs. Such light-generating photonic circuits can comprise dual-pumped amplifiers, multi-stage amplifiers, and master oscillator power amplifier (MOPA) laser sources. In these cases, a heterogeneous photonic circuit having multiple integrated pump modules can be beneficial instead of splitting and distributing optical output from a single integrated pump module.

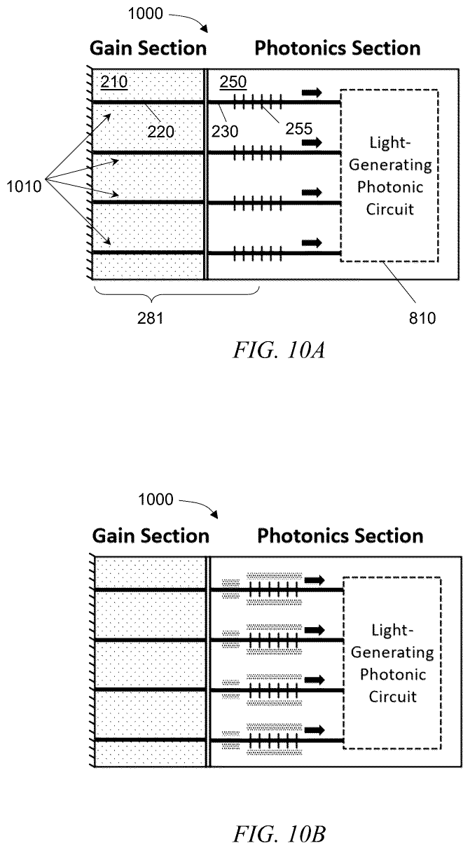

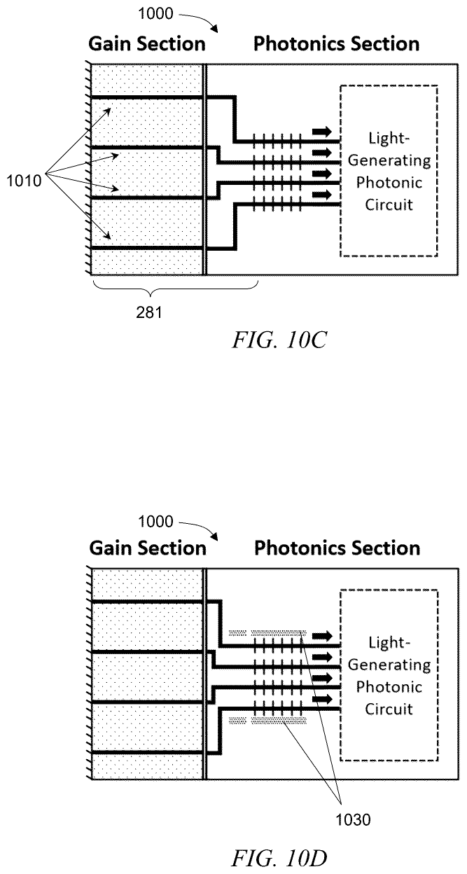

FIG. 10A depicts an example of a multi-pump-source, heterogeneous photonic circuit 1000 that comprises four integrated pump modules 1010 (implemented with four laser cavities 281). Fewer or more pump modules can be used in some implementations. Output power from the pump modules are provided to a light-generating photonic circuit 810 formed in the photonics section 250. Each of the integrated pump modules 1010 comprises a gain waveguide 220 in the gain section 210 that optically couples to an optical waveguide 230 and a reflector 255 (implemented as a DBR in the illustrated example) in the photonics section 250. The pump outputs need not be at identical wavelengths but can be at similar wavelengths (e.g., within 5, 10, 15, 20, or 25 nm of each other due to the utilization of the same gain section and/or gain material).

FIG. 10B depicts an implementation of a multi-pump-module, heterogeneous photonic circuit 1000 where the relationship between the optical outputs from the multiple integrated pump modules can be controlled. For example, tunable reflectors, tunable filters, and/or phase control elements can be included in the photonics section 250 for wavelength, power, and/or amplitude control as described above for a single integrated pump module. If an application uses pump outputs that are approximately or exactly at a same wavelength (e.g., for coherent beam combining), the output wavelengths can be stabilized with respect to each other and/or to a common frequency reference using optical components in the photonics section and feedback control as described above.

Another method to produce the same or approximately the same output wavelengths from each integrated pump module 1010 is depicted in FIG. 10C. In this approach, the reflector, filter, and/or phase control of each laser cavity 281 is located close to each other (e.g., within 1 to 100 microns of each other). During microfabrication, differences in structure height, refractive index, and width biases can correlate to differences in position of the structures on the wafer. Bringing the optical components in close proximity can reduce those differences and improve uniform operation across the devices. Having the reflectors, filters, and/or phase controls close together can also enable tuning by a single tuning element 1030, as depicted in FIG. 10D, which can simplify control of the multiple integrated pump modules.

Feedback mechanisms described above can be implemented with the multi-pump-module, heterogeneous photonic circuits 1000 described in connection with FIG. 10A through FIG. 10D. In some cases, feedback can be implemented individually for each integrated pump module (e.g., by monitoring the output from the pump module, light-generating photonic circuit, and/or an auxiliary photonic circuit or auxiliary device and providing feedback based on the monitored output to control that integrated pump module). In some cases, feedback can be implemented for a subset of (numbering more than one) or the entire group of the integrated pump modules (e.g., by monitoring the output(s) from one or more integrated pump modules, one or more light-generating photonic circuits, and/or one or more auxiliary photonic circuits or auxiliary devices and providing feedback to control the subset of, or the entire group of, the integrated pump modules).

Integrated pump modules described herein can be configured to provide pump radiation in an emission band of wavelengths characterized by a peak wavelength. The bandwidth of the emission band can be from 1 nm to 100 nm. The peak wavelength (defined as that wavelength having the highest intensity or power) can be from 350 nm to 3 microns, though longer wavelengths are possible in some cases. The light-generating photonic circuits described herein can output radiation in an emission band having a bandwidth from 1 nm to 100 nm and a peak wavelength in a range from 400 nm to 5 microns.

### 6. Conclusion

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. M ore generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments can be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts can be embodied as one or more methods, of which an example has been provided. The acts performed as part of the method can be ordered in any suitable way. Accordingly, embodiments can be constructed in which acts are performed in an order different than illustrated, which can include performing some acts simultaneously, even though depicted as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the components so conjoined, i.e., components that are conjunctively present in some cases and disjunctively present in other cases. Multiple components listed with “and/or” should be construed in the same fashion, i.e., “one or more” of the components so conjoined. Other components can optionally be present other than the components specifically identified by the “and/or” clause, whether related or unrelated to those components specifically identified. Thus, as a non-limiting example, a reference to “A and/or B”, when used in conjunction with open-ended language such as “comprising” can refer, in one embodiment, to A only (optionally including components other than B); in another embodiment, to B only (optionally including components other than A); in yet another embodiment, to both A and B (optionally including other components); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of components, and, optionally, additional unlisted items. Only terms clearly indicated to the contrary, such as “only one of” or “exactly one of,” or, when used in the claims, “consisting of,” will refer to the inclusion of exactly one component of a number or list of components. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more components, should be understood to mean at least one component selected from any one or more of the components in the list of components, but not necessarily including at least one of each and every component specifically listed within the list of components and not excluding any combinations of components in the list of components. This definition also allows that components can optionally be present other than the components specifically identified within the list of components to which the phrase “at least one” refers, whether related or unrelated to those components specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including components other than B); in another embodiment, to at least one, optionally including more than one, B, with no A present (and optionally including components other than A); in yet another embodiment, to at least one, optionally including more than one, A, and at least one, optionally including more than one, B (and optionally including other components); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A heterogeneous photonic circuit comprising:
a gain section comprising:
a gain waveguide, integrated with the gain section, to amplify light by stimulated emission in a laser cavity and to guide the light amplified by stimulated emission in the gain section; and
a photonics section optically coupled to the gain section, the photonics section comprising:
an optical waveguide, integrated with the photonics section and in optical communication with the gain waveguide, to receive the light amplified by stimulated emission from the gain section and to guide the light amplified by stimulated emission in the photonics section;
an output coupler, integrated with the photonics section and in optical communication with the optical waveguide to partially form the laser cavity of an integrated pump module, the output coupler configured to transmit the light amplified by stimulated emission from the laser cavity as a pump beam having a pump wavelength; and
a light-generating photonic circuit, integrated with the photonics section and in optical communication with the laser cavity, to:
receive the pump beam from the laser cavity, and
output a signal beam at a signal wavelength different than the pump wavelength in response to optical pumping of the light-generating photonic circuit by the pump beam.

2. The heterogeneous photonic circuit of claim 1, wherein the gain section is formed in a first material platform and the photonics section is formed in a second material platform different than the first material platform.

3. The heterogeneous photonic circuit of claim 2, wherein the first material platform comprises a Ill-V material to amplify the light by stimulated emission and the second material platform comprises at least one of silicon, silicon nitride, silicon dioxide, alumina, tantala, lithium niobate, or lithium tantalate.

4. The heterogeneous photonic circuit of claim 1, wherein the gain section comprises a die that is disposed in a trench formed in the photonics section.

5. The heterogeneous photonic circuit of claim 1, wherein the gain section comprises gain material that is heterogeneously integrated with the photonics section.

6. The heterogeneous photonic circuit of claim 1, wherein the output coupler comprises a distributed Bragg reflector (DBR) formed in the optical waveguide.

7. The heterogeneous photonic circuit of claim 6, wherein the DB R is tunable.

8. The heterogeneous photonic circuit of claim 1, wherein the output coupler comprises at least one of a ring resonator or a waveguide loop mirror.

9. The heterogeneous photonic circuit of claim 1, further comprising:
a tunable phase control element, integrated in the photonics section in optical communication with the optical waveguide in the laser cavity, to tune an optical path length of the laser cavity.

10. The heterogeneous photonic circuit of claim 1, further comprising:
a reflector optically coupled to a first end of the gain waveguide to reflect the light amplified by stimulated emission back along the gain waveguide.

11. The heterogeneous photonic circuit of claim 1, wherein the gain waveguide is butt-coupled to the optical waveguide.

12. The heterogeneous photonic circuit of claim 1, wherein the laser cavity comprises a waveguide formed in a loop.

13. The heterogeneous photonic circuit of claim 1, wherein the light-generating photonic circuit comprises one of an optical amplifier, a laser, or an optically nonlinear device.

14. The heterogeneous photonic circuit of claim 1, wherein the light-generating photonic circuit comprises a waveguide doped with a rare-earth ion or transition metal ion to generate or amplify radiation at the signal wavelength that is output in the signal beam.

15. The heterogeneous photonic circuit of claim 1, further comprising:
a photodetector arranged to detect an output from the integrated pump module or the light-generating photonic circuit; and
a processor configured to receive a signal from the photodetector and control at least one of a phase control element in optical communication with the laser cavity or a wavelength control element in optical communication with the laser cavity in response to receiving and processing the signal from the photodetector.

16. The heterogeneous photonic circuit of claim 1, further comprising:
a photodetector, in optical communication with the light-generating photonic circuit, to detect a residual amount of the pump beam from the light-generating photonic circuit.

17. The heterogeneous photonic circuit of claim 16, wherein:
the photodetector comprises a gain waveguide formed in the gain section, and
the gain waveguide is configured for reverse biasing.

18. The heterogeneous photonic circuit of claim 1, further comprising:
a third waveguide, integrated with the gain section, to guide additional light amplified by stimulated emission in the gain section; and
a fourth waveguide, integrated with the photonics section and in optical communication with the third waveguide, to guide the additional light amplified by stimulated emission in the gain section.

19. The heterogeneous photonic circuit of claim 18, further comprising:
a photodetector, in optical communication with the fourth waveguide, to detect at least some of the additional light amplified by stimulated emission in the gain section.

20. The heterogeneous photonic circuit of claim 1, wherein the optical waveguide is coupled to a first end of the gain waveguide, and further comprising:
a third waveguide, integrated with the photonics section in optical communication with the gain waveguide, coupled to a second end of the gain waveguide.

21. A heterogeneous photonic circuit comprising:
a gain section comprising:
a plurality of gain waveguides, integrated with the gain section, wherein:
each gain waveguide of the plurality of gain waveguides is configured to amplify light by stimulated emission in a laser cavity of a plurality of laser cavities formed partly in the gain section, and
each gain waveguide of the plurality of gain waveguides is configured to guide the light amplified by stimulated emission in the gain section; and
a photonics section optically coupled to the gain section, the photonics section comprising:
a plurality of optical waveguides, integrated with the photonics section and in optical communication with the plurality of gain waveguides, each optical waveguide of the plurality of optical waveguides arranged to receive the light amplified by stimulated emission from a corresponding gain waveguide of the plurality of gain waveguides and to guide the light amplified by stimulated emission in the photonics section;
a plurality of output couplers, wherein:
each output coupler of the plurality of output couplers is in optical communication with a corresponding optical waveguide of the plurality of optical waveguides to partially form a laser cavity of the plurality of laser cavities,
each laser cavity of the plurality of laser cavities forms an integrated pump module,
each output coupler of the plurality of output couplers is configured to transmit the light amplified by stimulated emission from the laser cavity and integrated pump module as a pump beam having a pump wavelength; and
a light-generating photonic circuit, integrated with the photonics section and in optical communication with the plurality of optical waveguides, to:
receive a plurality of pump beams from the plurality of optical waveguides, each pump beam of the plurality of pump beams comprising the light amplified by stimulated emission and having the pump wavelength, and
output at least one signal beam at a signal wavelength different than the pump wavelength of each pump beam of the plurality of pump beams in response to optical pumping of the light-generating photonic circuit by the plurality of pump beams.
